(19) United States
(12) Patent Application Publication
(10) Pub. No.: US 2015/0048423 A1
(43) Pub. Date: Feb. 19, 2015

(54) SEMICONDUCTOR DEVICE HAVING A III-V CRYSTALLINE COMPOUND MATERIAL SELECTIVELY GROWN ON THE BOTTOM OF A SPACE FORMED IN A SINGLE ELEMENT SUBSTRATE.

(71) Applicant: INTERNATIONAL BUSINESS MACHINES CORPORATION, Armonk, NY (US)

(72) Inventors: Robert L. Bruce, White Plains, NY (US); Cheng-Wei Cheng, White Plains, NY (US); Joel P. de Souza, Putnam Valley, NY (US); Ryan M. Martin, New York, NY (US); Uzma Rana, Chappaqua, NY (US); Devendra K. Sadana, Pleasantville, NY (US); Kuen-Ting Shiu, White Plains, NY (US); Yanning Sun, Scarsdale, NY (US)

(73) Assignee: INTERNATIONAL BUSINESS MACHINES CORPORATION, Armonk, NY (US)

(21) Appl. No.: 14/028,639

(22) Filed: Sep. 17, 2013

Related U.S. Application Data
(63) Continuation of application No. 13/968,756, filed on Aug. 16, 2013.

(51) Int. Cl. H01L 29/267

(52) U.S. Cl. CPC H01L 29/267
USPC 257/200

(57) ABSTRACT

A method for forming a crystalline compound material on a single element substrate includes etching a high aspect ratio trench in a single element crystalline substrate and forming a dielectric layer over the substrate and on sidewalls and a bottom of the trench. The dielectric is removed from the bottom of the trench to expose the substrate at the bottom of the trench. A crystalline compound material is selectively grown on the substrate at the bottom of the trench.

### RELATED APPLICATION DATA

This application is a Continuation application of co-pending U.S. patent application Ser. No. 13/968,756 filed on Aug. 16, 2013, incorporated herein by reference in its entirety.

### BACKGROUND

1. Technical Field

The present invention relates to semiconductor processing, and more particularly to methods and devices for preparing silicon for III-V material growth.

2. Description of the Related Art

Single-element semiconductors, such as silicon and germanium, often do not provide the performance or characteristics that are needed in the way that composite semiconductors, such as III-V materials, do. For example, these materials include different materials that create a direct bandgap property that permits for spontaneous emission not provided in single element semiconductors.

Because silicon processing is mature and commonly employed, there are many instances where single element and composite element semiconductors need to be employed together. However, growing III-V materials on silicon may be difficult. One method for growing III-V material on silicon includes selective III-V growth on Si by Aspect Ratio Trapping (ART). ART applies a thick thermally grown SiO₂ layer.

Trenches are formed in the SiO₂ layer over the silicon substrate. The III-V material is grown between partitions in the SiO₂ layer. The defect density is reduced largely by trench trapping. A higher aspect ratio gives a better trapping effect. Therefore, a higher aspect ratio SiO₂ trench is preferred and needed, and thermally grown SiO₂ provides good growth selectivity. However, thick SiO₂ growth requires high processing temperatures and a long growth time.

### SUMMARY

A method for forming a crystalline compound material on a single element substrate includes etching a high aspect ratio trench in a single element crystalline substrate and forming a dielectric layer over the substrate and on sidewalls and a bottom of the trench. The dielectric is removed from the bottom of the trench to expose the substrate at the bottom of the trench. A crystalline compound material is selectively grown on the substrate at the bottom of the trench.

Another method for forming a crystalline compound material on a single element substrate includes etching a single element crystalline substrate to form a subsurface space having sidewalls in the space laterally extending beyond a top surface opening in the substrate; forming a dielectric layer over the substrate and on sidewalls and a bottom of the space; removing the dielectric from the bottom of the space to expose the substrate at the bottom of the space; and selectively growing a crystalline compound material on the substrate at the bottom of the space.

A semiconductor device includes a single element substrate and a subsurface space formed in the single element crystalline substrate. A dielectric layer is formed over the substrate and on sidewalls of the space. A III-V crystalline compound material is selectively grown on the substrate at the bottom of the space.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a single element substrate having a dielectric layer patterned thereon in accordance with the present principles;

FIG. 2A is a cross-sectional view of the single element substrate having a trench formed therein in accordance with one embodiment;

FIG. 2B is a cross-sectional view of the single element substrate having a space formed therein in accordance with one embodiment;

FIG. 3A is a cross-sectional view of the single element substrate having a thermally grown dielectric layer over a top surface, sidewalls and a bottom of the trench in accordance with one embodiment;

FIG. 3B is a cross-sectional view of the single element substrate having a thermally grown dielectric layer over a top surface, sidewalls and a bottom of the space in accordance with one embodiment;

FIG. 4A is a cross-sectional view of the single element substrate having the thermally grown dielectric layer removed from the bottom of the trench in accordance with one embodiment;

FIG. 4B is a cross-sectional view of the single element substrate having the thermally grown dielectric layer removed from the bottom of the space in accordance with one embodiment;

FIG. 5A is a cross-sectional view of the single element substrate having a selectively grown crystalline compound material formed from the bottom of the trench in accordance with one embodiment;

FIG. 5B is a cross-sectional view of the single element substrate having a selectively grown crystalline compound material formed from the bottom of the space in accordance with one embodiment;

FIG. 6 is a cross-sectional view of the single element substrate having a trench formed therein in accordance with another embodiment;

FIG. 7 is a cross-sectional view of the single element substrate having a space formed therein by etching the trench of FIG. 6 in accordance with another embodiment;

FIG. 8 is a scanning electron microscope image showing a III-V material grown on a Si substrate in accordance with the present principles; and

FIG. 9 is a block/flow diagram showing a method for growing a crystalline compound material on a single element substrate in accordance with illustrative embodiments.

### DETAILED DESCRIPTION OF PREFERRED EMBODIMENTS

In accordance with the present principles, methods and devices are provided where III-V material is grown from a sub-surface of a single element substrate. A mask is provided or formed on the single element substrate, and a reactive ion etch process is performed on the substrate to form high aspect ratio trenches (or spaces) below the surface of the substrate. Exposed surfaces of the substrate within the trench are employed to thermally grow a thin dielectric layer (e.g., SiO₂). Since the high aspect ratio trench is subsurface, the thickness of the dielectric layer is substantially thinner. This results in a much shorter processing time to form the dielectric layer. An area of the trench is further etched to expose material of the substrate onto which III-V material is grown. Defects remain buried below the surface of the substrate.

It is to be understood that the present invention will be described in terms of a given illustrative architecture having a wafer or substrate of one semiconductor material for growing a second semiconductor material; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In accordance with the present embodiments, a design for an integrated circuit chip may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

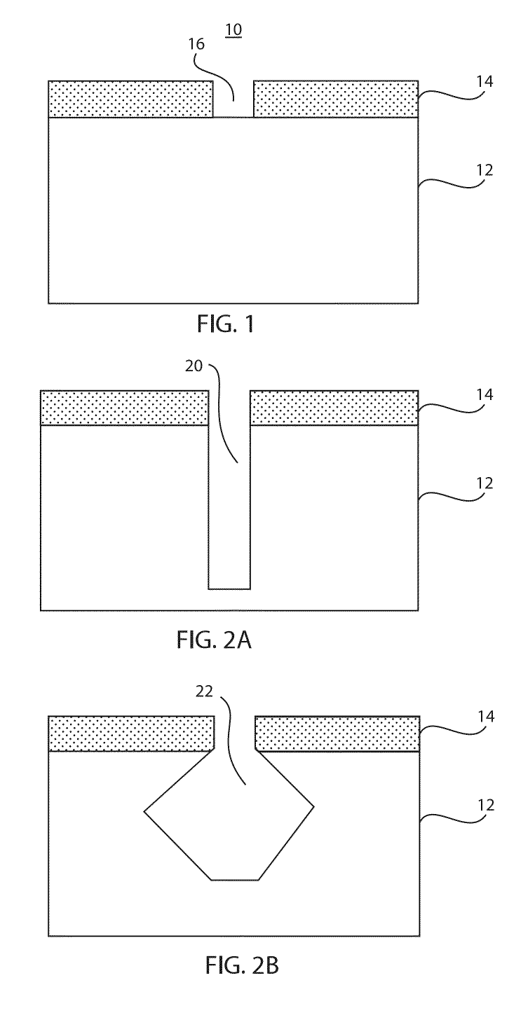

Referring now to the drawings in which like numerals represent the same or similar elements and initially to FIG. 1, a cross-sectional view of a substrate 12 having a dielectric layer 14 formed thereon is illustratively depicted. While the substrate 12 preferably includes monocrystalline bulk silicon, it should be understood that substrate 12 may include SiGe, SiC, Ge, semiconductor-on-insulator (SOI), etc. The substrate 12 should be cleaned, e.g., by an RCA process or the like, prior to formation of any layers thereon.

Dielectric layer 14 may include an oxide, a nitride or other mask materials. Examples of oxides include SiO₂, Al₂O₃, etc., and examples of nitrides include SiN, SiON, etc. Dielectric layer 14 may be considered an etch mask layer, and includes a material that can be employed to etch a deep trench in the substrate 12. In one embodiment, the substrate 12 includes monocrystalline Si and the dielectric layer 14 includes a thermally grown SiO₂ layer.

A thermally grown SiO₂ layer is preferable for dielectric layer 14, although the dielectric layer 14 may also be formed by chemical vapor deposition (CVD) or atomic layer deposition (ALD). Thermal oxide has the lowest dangling bond defects and is therefore capable of providing better growth selectivity during the III-V epitaxy. In accordance with the present principles, the dielectric layer 14 need only be between about 0.01 and about 0.5 microns, and may be formed with a processing temperature of between 800 and 1200 degrees C. for between about 0.5 to about 3 hours.

The dielectric layer 14 is patterned to identify locations for the placement of trenches. A reactive ion etch (RIE) process may be employed to form openings 16 in the dielectric layer 14 and expose portions of the substrate 12.

Referring to FIG. 2A, a RIE process is employed to etch a high aspect ratio trench 20 into the substrate 12 through the opening 16. A high aspect ratio may be considered 1:1 (height to width) or greater and preferably 2:1 or greater. The depth of the trench 20 may be about 0.1 to about 10 microns. The RIE may include known etch chemistries, e.g., oxygen plasma, etc. The dielectric layer 14 acts as a mask for the etch, and the dielectric layer 14 may be removed after the RIE. In a particularly useful embodiment, the dielectric layer 14 includes a thermally grown silicon oxide, which remains on the surface of the substrate 12 after the RIE.

Referring to FIG. 2B, a selective etch process is employed to etch a space or trench 22 inside the substrate 12. The trench 22 may be of any shape and extend beyond the boundaries of the opening 16 in the dielectric layer 14. Selective etching may include an isotropic etch. The selective etching may include a plasma etch, a dry etch or a wet etch. In one embodiment, the selective etch include fluorine-based plasma, such as xenon difluoride (XeF₂). The dielectric layer 14 acts as a mask for the etch, and the dielectric layer 14 may be removed after the selective etch. In a particularly useful embodiment, the dielectric layer 14 includes a thermally grown silicon oxide, which remains on the surface of the substrate 12 after the selective etch.

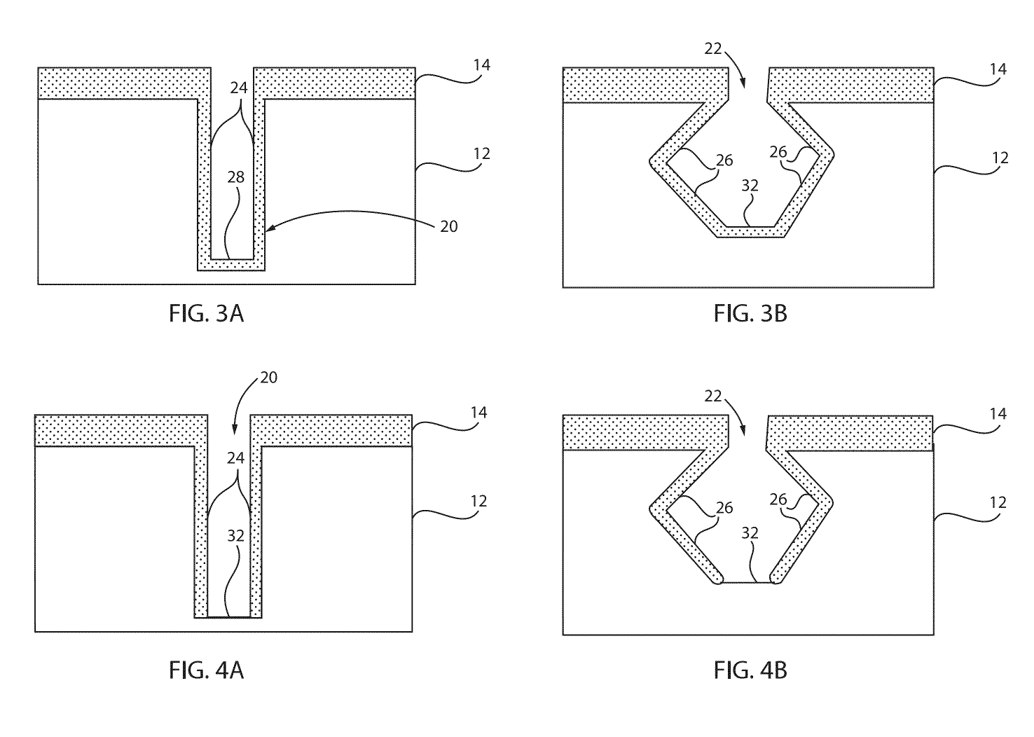

Referring to FIG. 3A, a thermal oxidation process may be employed to form a thermal oxide 24, 28, respectively on sidewalls and a bottom of the trench 20. The oxide 24, 28 is thin since the oxide 24 on the sidewalls of the trench 20 is merely an interface for the later formed III-V material that will be grown. The oxidation process may include an oxidizing environment having a processing temperature of between 800 and 1200 degrees C. for between about 0.5 to about 3 hours to provide a thickness between about 10 nm and about 500 nm of oxide 24, 28, respectively on the sidewalls and the bottom of the trench 20. Layer 24, 28 may also be formed by chemical vapor deposition (CVD) or atomic layer deposition (ALD) with thickness ranges from about 10 nm to about 500 nm.

Referring to FIG. 3B, a thermal oxidation process may be employed to form a thermal oxide 26, 30, respectively on sidewalls and a bottom of the trench 22. The oxide 26, 30 is thin since the oxide 26 on the sidewalls of the trench 22 is merely an interface for the later formed III-V material that will be grown. The oxidation process may include an oxidizing environment having a processing temperature of between 800 and 1200 degrees C. for between about 0.5 to about 3 hours to provide a thickness between about 10 nm and about 500 nm of the oxide 26, 30, respectively on the sidewalls and the bottom of the trench or space 22. Layer 26, 30 may also be formed by CVD or ALD with thickness ranges from about 10 nm to about 500 nm.

Referring to FIG. 4A, a RIE process is employed to etch the oxide 28 on the bottom of the trench 20 to expose a surface 32 of the substrate 12. The RIE may include known etch chemistries.

Referring to FIG. 4B, a RIE process is employed to etch the oxide 30 on the bottom of the trench 22 to expose a surface 32 of the substrate 12. The RIE may include known etch chemistries.

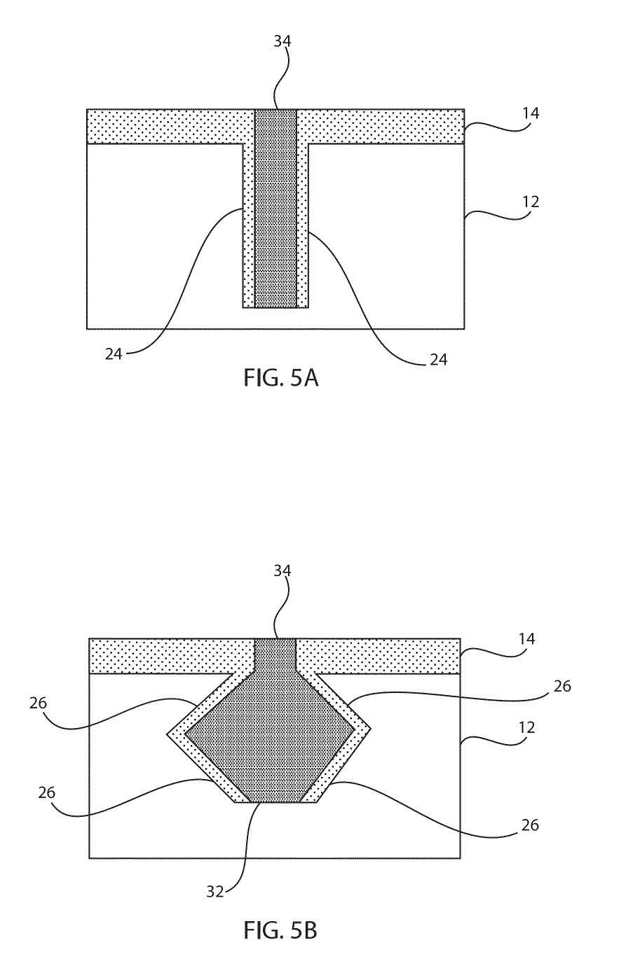

Referring to FIG. 5A, an epitaxial growth process is employed to grow a III-V semiconductor material 34 (or other semiconductor material (II-VI, etc.)). The III-V material 34 is preferably selectively grown starting on surface 32. The growth process begins on the surface 32 and grows up to a top surface or beyond. The III-V material 34 may include, e.g., GaAs, GaN, InP, AlP, AlN, etc. Since the III-V material 34 is confined within the dielectric layer 24 formed on sidewalls of the substrate 12, a high aspect ratio trench 20 is employed for aspect ratio trapping (ART) to confine crystal defects when growing a monolithically integrated III-V/Si device. The III-V material 34 is formed subsurface in the substrate 12, and defects are confined deep in the trench bottom.

Referring to FIG. 5B, an epitaxial growth process is employed to grow a III-V semiconductor material 34 (or other semiconductor material (II-VI, etc.)). The III-V material 34 is preferably selectively grown starting on surface 32. The growth process begins on the surface 32 and grows up to a top surface or beyond. The III-V material 34 may include, e.g., GaAs, GaN, InP, AlP, AlN, etc. Since the III-V material 34 is confined within the dielectric layer 26 formed on sidewalls of the substrate 12, the space 22 is employed to confine crystal defects to an interface region between III-V material 34 and the surface 32 of the substrate 12. The III-V material 34 is formed subsurface in the substrate 12, and defects are confined deep in the bottom of the space 22.

The III-V material 34 may be further grown and processed to form transistors, lasers, diodes, or any other electronic device. The substrate 12 and dielectric layer 14 may also be employed for forming transistors or any other electronic device. Processing may continue with the formation of back end of the line (BEOL) structures and the like.

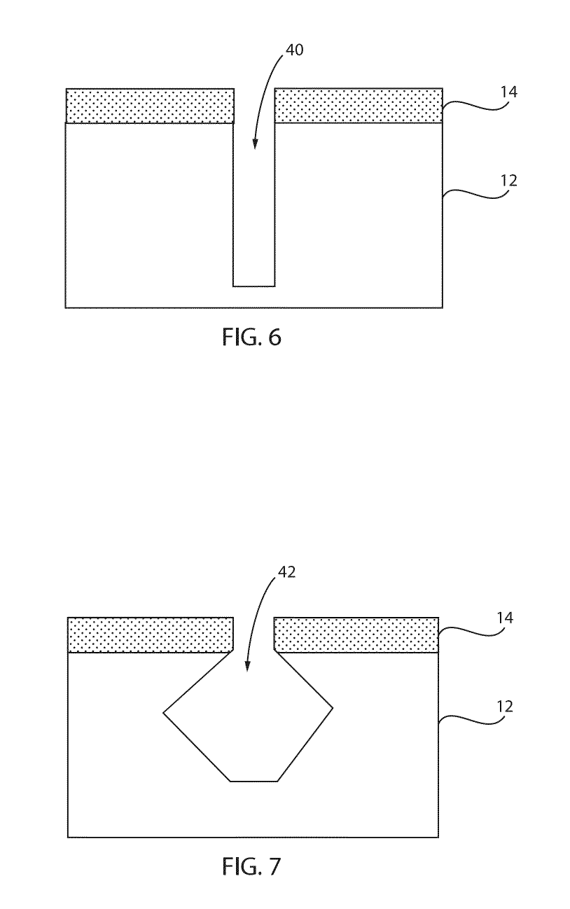

Referring to FIGS. 6 and 7, in an alternate embodiment, a deep trench 40 may be formed in the substrate 12 using a RIE process, as before. Then, a wet etch is performed to expand a subsurface space 42 within the substrate 12. In one particularly useful embodiment, potassium hydroxide (KOH) is employed to etch the substrate 12, e.g., along crystal planes to expand the space 42. The wafer of substrate 12 may be dipped in a KOH solution, which is preferably diluted. Processing continues with FIG. 3B.

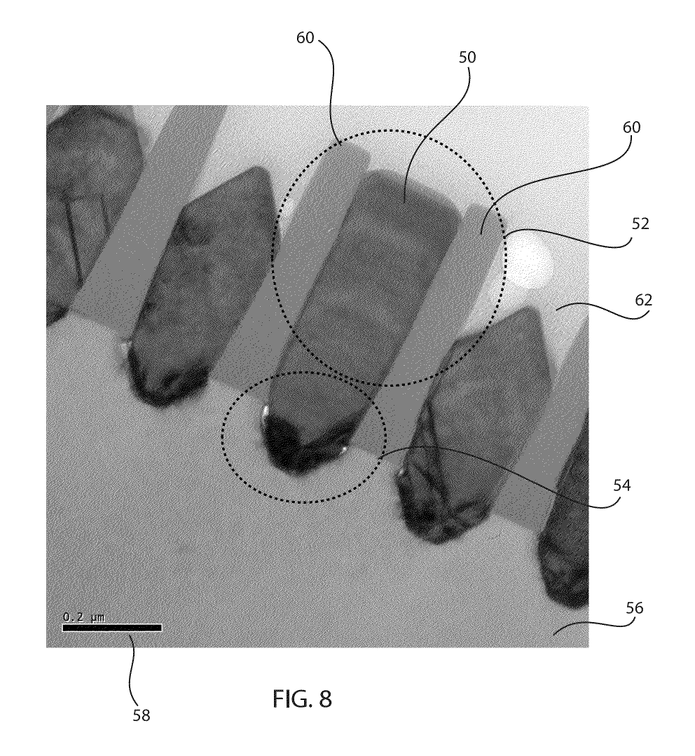

Referring to FIG. 8, a scanning electron microscope (SEM) image shows a silicon substrate 56 having a thermal oxide (SiO₂) grown thereon and patterned to form holes 62 therein. A III-V material 50, in this case GaAs, is grown from the substrate 56. A lower portion 54 of the III-V material 50 shows defects, which are confined in the lower portion 54. An upper portion 52 of the III-V material 50 is defect free.

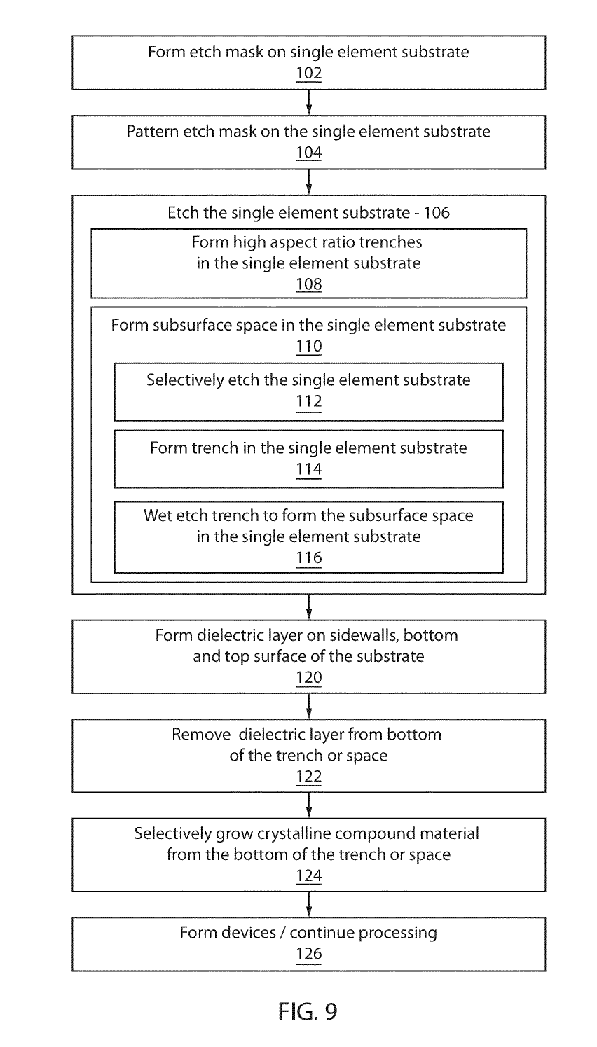

Referring to FIG. 9, methods for forming a crystalline compound material on a single element substrate are shown. It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

In block 102, a dielectric or etch mask layer is grown or deposited over a single element substrate (e.g., Si). It should be understood that single element refers to a composition of the substrate on which a growing surface is employed for growing a crystalline compound material. Therefore, the single element substrate may include a SOI substrate or the like. In block 104, the dielectric or etch mask layer is patterned using e.g., a mask and a RIE process. The pattern includes openings that expose the substrate.

In block 106, the substrate is etched. In block 108, a high aspect ratio trench is etched in the substrate. The high aspect ratio trench may include a height to width aspect ratio of greater than about 1:1. In block 110, the substrate is etched to form a subsurface space having sidewalls in the space extending beyond a top surface opening in the substrate. In block 112, the space may be formed by selectively etching the substrate in a plasma, dry or wet etch. In one embodiment, etching the single element crystalline substrate includes forming a trench in the substrate, in block 114, and wet etching the substrate with KOH to form the space in block 116.

In block 120, a dielectric layer (e.g., thermally grown or formed by CVD deposition, or by ALD deposition) is formed over the substrate and on sidewalls and a bottom of the trench or space. The substrate preferably includes monocrystalline silicon and the dielectric layer preferably includes a silicon dioxide layer. The silicon dioxide layer may include a thickness of 500 nm or less on sidewalls of the trench or space.

In block 122, the dielectric is removed from the bottom of the trench or space to expose the substrate at the bottom of the trench or space. In block 124, a crystalline compound material is selectively grown on the substrate at the bottom of the trench or space. Selectively growing the crystalline compound material includes epitaxially growing the crystalline compound material below a surface of the substrate. The crystalline compound material may include a crystalline III-V material, although other semiconductor materials may be employed. In block 126, processing continues by forming the crystalline compound material and/or the single element substrate into electronic devices.

Having described preferred embodiments for silicon substrate preparation for selective III-V epitaxy (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device, comprising:
a single element substrate;
a subsurface space formed in the single element crystalline substrate;
a dielectric layer formed over the substrate and on sidewalls of the space; and
a III-V crystalline compound material selectively grown on the substrate at the bottom of the space.

2. The device as recited in claim 1, wherein defects in the crystalline compound material exist below a surface of the substrate.

3. The device as recited in claim 1, wherein the space includes one of a high aspect ratio trench and a volume having the sidewalls extending laterally beyond a surface opening in the substrate.

4. The device as recited in claim 1, wherein the substrate includes monocrystalline silicon and the dielectric layer includes a silicon dioxide layer wherein the silicon dioxide layer includes a thickness of 500 nm or less on the sidewalls.

5. The device as recited in claim 1, wherein the III-V crystalline compound material is included in an electronic device.
